(19) United States
(12) Patent Application Publication
(10) Pub. No.: US 2022/0149571 A1
(43) Pub. Date: May 12, 2022

(54) TECHNOLOGIES FOR A SMART ELECTRICAL OUTLET AND A SMART ELECTRICAL CORD

(71) Applicant: Grid Connect Inc., Naperville, IL (US)

(72) Inventors: Cristian Codreanu, Chicago, IL (US); Michael Justice, Naperville, IL (US); Adam Justice, Naperville, IL (US)

(21) Appl. No.: 17/094,477

(22) Filed: Nov. 10, 2020

(51) Int. Cl. H01R 13/66; H01R 25/00; H01R 13/70; G01R 31/68; G05B 15/02

(52) U.S. Cl. CPC H01R 13/6683; H01R 25/006; H01R 24/20; G01R 31/68; G05B 15/02; H01R 13/701

(57) ABSTRACT

A device for providing a connection to electrical energy, the device includes an electrical outlet with at least one receptacle, a control circuit and functionality to generate one or more electrical pulses to indicate whether there is an insertion, or a lack of an insertion, into the at least one electrical receptacle. The device can be an in-wall electrical outlet and/or a power-cord based electrical outlet. The device includes a capacitive touch array comprising a plurality of capacitive touch buttons. The capacitive touch buttons control a plurality of function of the at least one receptacle, based on at least a user interaction with the plurality of capacitive touch buttons. The device may also monitor, display and/or transmit a plurality of electrical usage data related to a device powered by the electrical outlet. The functionality of the outlet may also be provided as part of a power cord coupled to a device and inserted into an electrical outlet.

### TECHNICAL FIELD OF THE DISCLOSED EMBODIMENTS

The presently disclosed embodiments generally relate to an electrical outlet, and more particularly, to a device for detecting an insertion, or lack of an insertion, of a power cord into an electrical receptacle of an electrical outlet.

### BACKGROUND

In many residential, commercial, and/or industrial environments, both in the USA and around the world, electrical devices that require electrical service providing a nominal alternating current (AC) voltage, such as 115 Volts (V) or 220 V, often at fifteen (15) amperes (Amps) or (20) twenty Amps current capacity, among other current capacities, may be connected to such electrical service via electrical outlets. The electrical outlets could be in-wall electrical outlets (IWO) and/or power-cord-based electrical outlets. The electrical outlets are energized by an electrical energy power distribution system, usually located in or near the residential, commercial, and/or industrial environments.

The electrical outlets may take various shapes and/or sizes. The electrical outlets may include one or more different connector element/pin configurations, that may include external (e.g. “male”) components and/or internal (e.g., “female) components. Electrical outlets may conform to one or more industrial, scientific, and/or governmental standards.

For example, an in-wall electrical outlet may take the form of a single unit comprising two electrical outlet “sockets” (e.g., a duplex in-wall electrical outlet in which the connector element/pin configuration includes internal components). For example, a power-cord-based electrical outlet may include one or more (e.g., four (4), six (6), or eight (8)) electrical outlets (e.g., four, six, or eight electrical outlets in which the connector element/pin configuration includes internal components).

The electrical devices that use the electrical service may include one or more plug connectors, or “plug.” Plug connectors may take various shapes and/or sizes. A plug may include one or more different connector element/pin configurations, that may include external (e.g. “male”) components and/or internal (e.g., “female) components. For example, a plug that includes external connector/pin components may be inserted into an electrical outlet includes internal connector/pin components. Plug connectors may conform to one or more industrial, scientific, and/or governmental standards.

### SUMMARY OF THE DISCLOSED EMBODIMENTS

One or more devices, systems, methods, may implement one or more techniques to detect if a plug is inserted into an electrical outlet, either an in-wall electrical outlet and/or a power-cord-based electrical outlet. In one or more techniques, plug insertion may be detected in the electrical outlet with the device attached to the plug being powered or not being powered.

In one or more techniques, a capacitive touch array and/or array button may be used to locally control power for one or more of the electrical outlets of the in-wall electrical outlet and/or the power-cord-based electrical outlet. In one or more techniques, the capacitive touch array and/or array button may be located on a circuit board under the front plate of the in-wall electrical outlet and/or the power-cord-based electrical outlet.

In one or more techniques, electrical energy (e.g., electrical current draw/load) overload the in-wall electrical outlet and/or the power-cord-based electrical outlet may be monitored, controlled, and/or interlocked based on one or more instant current measurements, one or more peak current measurements, and/or one or more root-mean-squared (RMS) current measurements.

In one or more techniques, an intelligent architecture may reduce the scenarios or instances in which a reset, or resetting, may be required or useful of firmware running on an internal micro-controller and/or control circuit of the in-wall electrical outlet and/or the power-cord-based electrical outlet.

In one or more techniques, the circuitry inside the smart outlet may be integrated into a power cord to remotely connect to devices via wireless communication. This may allow devices to be turned on/off from remote locations. The smart outlet circuitry may include a user interface or display to indicate some of the operating parameters/data relative to the operation of the smart outlet. In some embodiments, the operating parameters/data relative to the operation of the smart outlet may be wirelessly transmitted to an external device.

### BRIEF DESCRIPTION OF DRAWINGS

The embodiments and other features, advantages and disclosures contained herein, and the manner of attaining them, will become apparent and the present disclosure will be better understood by reference to the following description of various examples of the present disclosure taken in conjunction with the accompanying drawings, wherein:

FIGS. 1A & 1B are an example diagram of a computer/processing device wherein one or more of the techniques of the disclosure may be implemented according to an embodiment;

FIG. 2 illustrates an example of an electrical outlet insertion detection circuit diagram according to an embodiment;

FIG. 3 illustrates an example electrical outlet insertion detection scenario according to an embodiment;

FIG. 4 illustrates an example electrical outlet insertion detection scenario according to an embodiment;

FIG. 5 is an example illustration of an electrical outlet that includes capacitive touch components according to an embodiment;

FIG. 6 is an example illustration of an electrical outlet that that includes capacitive touch components according to an embodiment;

FIG. 7 is an example illustration of an electrical outlet that that includes capacitive touch components according to an embodiment;

FIG. 8 illustrates an example of an electrical outlet modular architecture circuit diagram according to an embodiment; and

FIG. 9 illustrates a power cord system according to an embodiment.

### DETAILED DESCRIPTION OF THE DISCLOSED EMBODIMENT

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

One or more devices, systems, methods, may implement one or more techniques to detect if a plug is inserted into an electrical outlet, either an in-wall electrical outlet and/or a power-cord-based electrical outlet. In one or more techniques, plug insertion may be detected in the electrical outlet with the device attached to the plug being powered or not being powered.

In one or more techniques, a capacitive touch array and/or array button may be used to locally control power for one or more of the electrical outlets of the in-wall electrical outlet and/or the power-cord-based electrical outlet. In one or more techniques, the capacitive touch array and/or array button may be located on a circuit board under the front plate of the in—wall electrical outlet and/or the power-cord-based electrical outlet.

In one or more techniques, electrical energy (e.g., electrical current draw/load) overload the in-wall electrical outlet and/or the power-cord-based electrical outlet may be monitored, controlled, and/or interlocked based on one or more instant current measurements, one or more peak current measurements, and/or one or more root-mean-squared (RMS) current measurements.

In one or more techniques, an intelligent architecture may reduce the scenarios or instances in which a reset, or resetting, may be required or useful of firmware running on an internal micro-controller and/or control circuit of the in-wall electrical outlet and/or the power-cord-based electrical outlet.

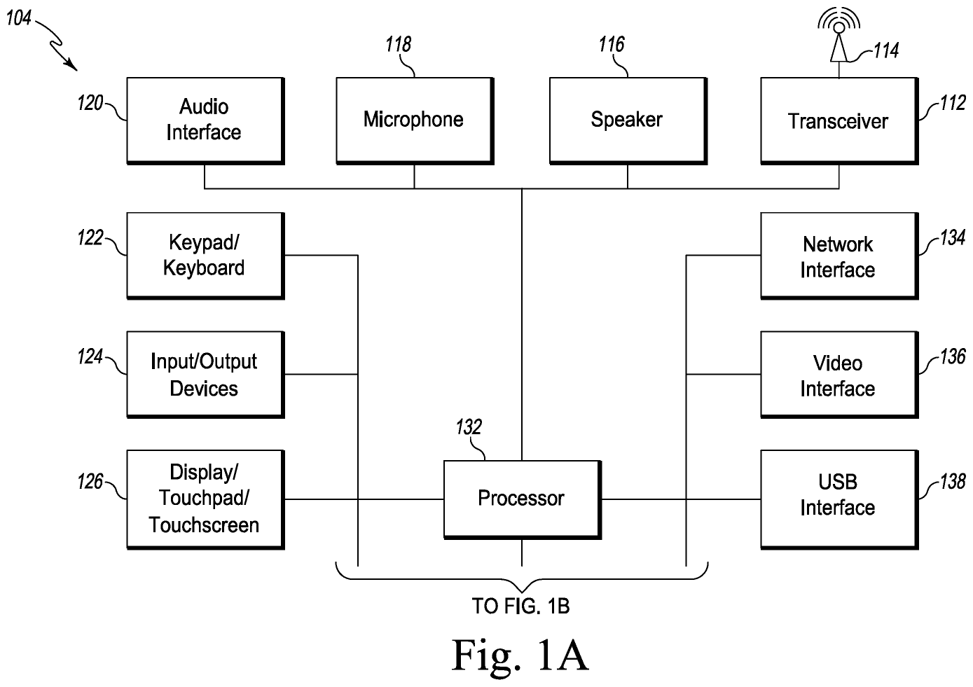

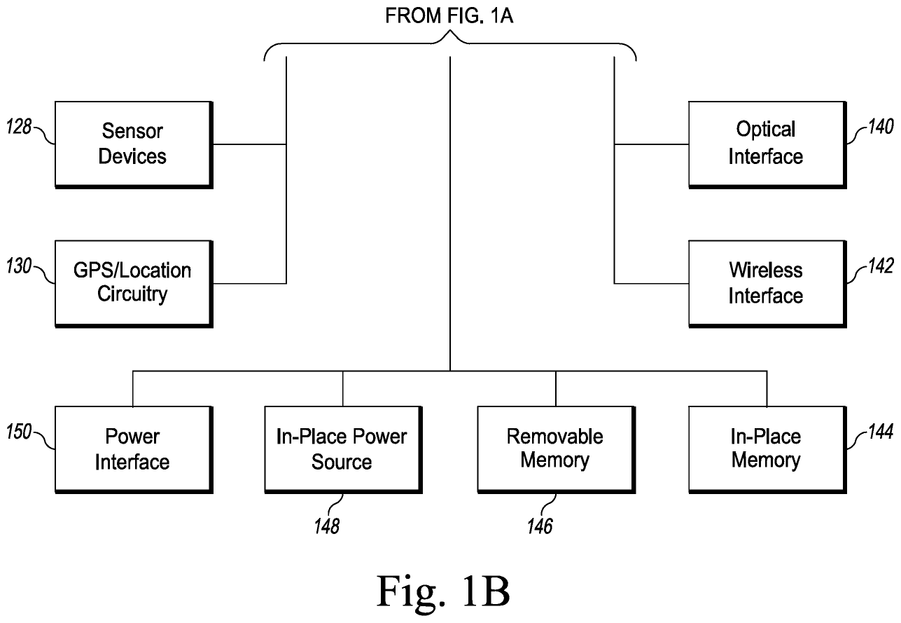

FIG. 1 is a diagram of an example computer/computing (e.g., processing) device 104 that may implement one or more techniques described herein, in whole or at least in part, with respect to one or more of the devices, methods, and/or systems described herein. In FIG. 1, the computing device 104 may include one or more of: a processor 132, a transceiver 112, a transmit/receive element (e.g., antenna) 114, a speaker 116, a microphone 118, an audio interface (e.g., earphone interface and/or audio cable receptacle) 120, a keypad/keyboard 122, one or more input/output devices 124, a display/touchpad/touch screen 126, one or more sensor devices 128, Global Positioning System (GPS)/location circuitry 130, a network interface 134, a video interface 136, a Universal Serial Bus (USB) Interface 138, an optical interface 140, a wireless interface 142, in-place (e.g., non-removable) memory 144, removable memory 146, an in-place (e.g., removable or non-removable) power source 148, and/or a power interface 150 (e.g., power/data cable receptacle). The computing device 104 may include one or more, or any sub-combination, of the aforementioned elements.

The computing device 104 may take the form of a laptop computer, a desktop computer, a computer mainframe, a server, a terminal, a tablet, a smartphone, and/or a cloud-based computing device (e.g., at least partially), and/or the like.

The processor 132 may be a general-purpose processor, a special-purpose processor, a conventional processor, a digital-signal processor (DSP), a plurality of microprocessors, one or more microprocessors in association with a DSP core, a controller, a microcontroller, one or more Application Specific Integrated Circuits (ASICs), one or more Field Programmable Gate Array (FPGAs) circuits, any other type of integrated circuit (IC), and/or a finite-state machine, and/or the like. The processor 132 may perform signal coding, data processing, power control, sensor control, interface control, video control, audio control, input/output processing, and/or any other functionality that enables the computing device 104 to serve as and/or perform as (e.g., at least partially) one or more of the devices, methods, and/or systems disclosed herein.

The processor 132 may be connected to the transceiver 112, which may be connected to the transmit/receive element 124. The processor 132 and the transceiver 112 may operate as connected separate components (as shown). The processer 132 and the transceiver 112 may be integrated together in an electronic package or chip (not shown).

The transmit/receive element 114 may be configured to transmit signals to, and/or receive signals from, one or more wireless transmit/receive sources (not shown). For example, the transmit/receive element 114 may be an antenna configured to transmit and/or receive RF signals. The transmit/receive element 114 may be an emitter/detector configured to transmit and/or receive IR, UV, or visible light signals, for example. The transmit/receive element 114 may be configured to transmit and/or receive RF and/or light signals. The transmit/receive element 114 may be configured to transmit and/or receive any combination of wireless signals.

Although the transmit/receive element 114 is shown as a single element, the computing device 104 may include any number of transmit/receive elements 114 (e.g., the same as for any of the elements 112-150). The computing device 104 may employ Multiple-Input and Multiple-Output (MIMO) technology. For example, the computing device 104 may include two or more transmit/receive elements 114 for transmitting and/or receiving wireless signals.

The transceiver 112 may be configured to modulate the signals that are to be transmitted by the transmit/receive element 114 and/or to demodulate the signals that are received by the transmit/receive element 114. The transceiver 112 may include multiple transceivers for enabling the computing device 104 to communicate via one or more, or multiple, radio access technologies, such as Universal Terrestrial Radio Access (UTRA), Evolved UTRA (E-UTRA), and/or IEEE 802.11, for example.

The processor 132 may be connected to, may receive user input data from, and/or may send (e.g., as output) user data to: the speaker 116, microphone 118, the keypad/keyboard 122, and/or the display/touchpad/touchscreen 126 (e.g., a liquid crystal display (LCD) display unit or organic light-emitting diode (OLED) display unit, among others). The processor 132 may retrieve information/data from and/or store information/data in, any type of suitable memory, such as the in-place memory 144 and/or the removable memory 146. The in-place memory 144 may include random-access memory (RAM), read-only memory (ROM), a register, cache memory, semiconductor memory devices, and/or a hard disk, and/or any other type of memory storage device.

The removable memory 146 may include a subscriber identity module (SIM) card, a portable hard drive, a memory stick, and/or a secure digital (SD) memory card, and/or the like. The processor 132 may retrieve information/data from, and/or store information/data in, memory that might not be physically located on the computing device 104, such as on a server, the cloud, and/or a home computer (not shown).

One or more of the elements 112-146 may receive power from the in-place power source 148. In-place power source 148 may be configured to distribute and/or control the power to one or more of the elements 112-146 of the computing device 104. The in-place power source 148 may be any suitable device for powering the computing device 104. For example, the in-place power source 148 may include one or more dry cell batteries (e.g., nickel-cadmium (NiCd), nickel-zinc (NiZn), nickel metal hydride (NiMH), lithium-ion (Li-ion), etc.), solar cells, and/or fuel cells, and/or the like.

Power interface 150 may include a receptacle and/or a power adapter (e.g., transformer, regulator, and/or rectifier) that may receive externally sourced power via one or more AC and/or DC power cables, and/or via wireless power transmission. Any power received via power interface 150 may energize one or more of the elements 112-146 of computing device 104, perhaps for example exclusively or in parallel with in-place power source 148. Any power received via power interface 150 may be used to charge in-place power source 148.

The processor 132 may be connected to the GPS/location circuitry 130, which may be configured to provide location information (e.g., longitude and/or latitude) regarding the current location of the computing device 104. The computing device 104 may acquire location information by way of any suitable location-determination technique.

The processor 132 may be connected to the one or more input/output devices 124, which may include one or more software and/or hardware modules that provide additional features, functionality and/or wired and/or wireless connectivity. For example, the one or more input/output devices 124 may include a digital camera (e.g., for photographs and/or video), a hands free headset, a digital music player, a media player, a frequency modulated (FM) radio unit, an Internet browser, and/or a video game player module, and/or the like.

The processor 132 may be connected to the one or more sensor devices 128, which may include one or more software and/or hardware modules that provide additional features, functionality and/or wired and/or wireless connectivity. For example, the one or more sensor devices 128 may include an accelerometer, an e-compass, and/or a vibration device, and/or the like.

The processor 132 may be connected to the network interface 134, which may include one or more software and/or hardware modules that provide additional features, functionality and/or wireless and/or wired connectivity. For example, the network interface 134 may include a Network Interface Controller (NIC) module, a Local Area Network (LAN) module, an Ethernet module, a Physical Network Interface (PNI) module, and/or an IEEE 802 module, and/or the like.

The processor 132 may be connected to the video interface 136, which may include one or more software and/or hardware modules that provide additional features, functionality and/or wired and/or wireless connectivity. For example, the video interface 136 may include a High-Definition Multimedia Interface (HDMI) module, a Digital Visual Interface (DVI) module, a Super Video Graphics Array (SVGA) module, and/or a Video Graphics Array (VGA) module, and/or the like.

The processor 132 may be connected to the USB interface 138, which may include one or more software and/or hardware modules that provide additional features, functionality and/or wired and/or wireless connectivity. For example, the USB interface 138 may include a universal serial bus (USB) port, and/or the like.

The processor 132 may be connected to the optical interface 140, which may include one or more software and/or hardware modules that provide additional features, functionality and/or wired and/or wireless connectivity. For example, the optical interface 140 may include a read/write Compact Disc module, a read/write Digital Versatile Disc (DVD) module, and/or a read/write Blu-Ray™ disc module, and/or the like.

The processor 132 may be connected to the wireless interface 142, which may include one or more software and/or hardware modules that provide additional features, functionality and/or wireless connectivity. For example, the wireless interface 142 may include a Bluetooth® module, an Ultra-Wideband (UWB) module, a ZigBee module, and/or a Wi-Fi (IEEE 802.11) module, and/or the like.

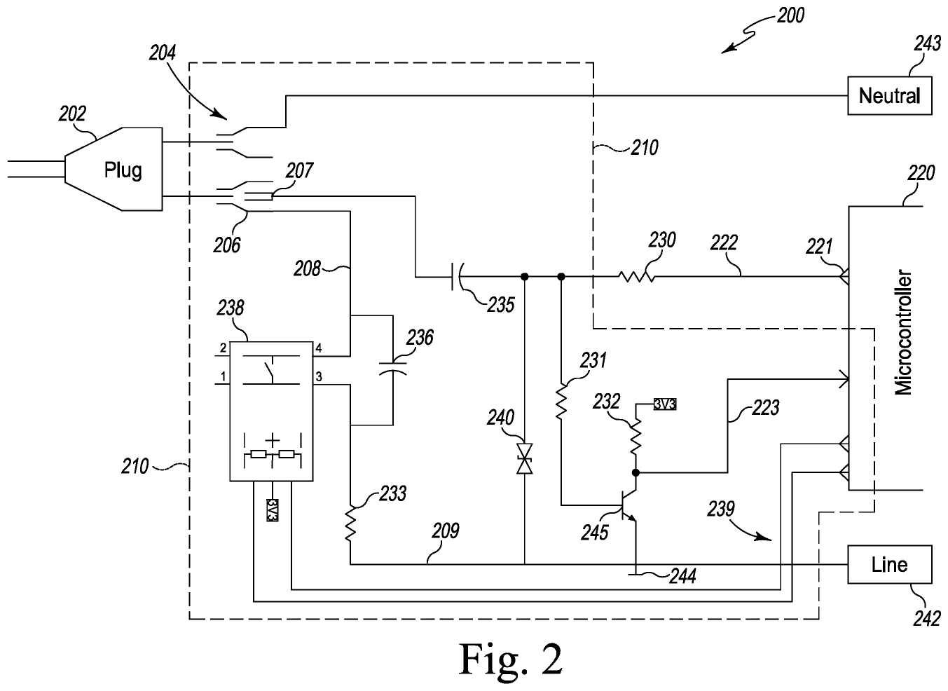

FIG. 2 illustrates an example of an electrical outlet insertion detection circuit diagram 200. One or more techniques may provide for detection of a plug 202 insertion into an electrical outlet 204, and/or detection of a lack of a plug 202 insertion into the electrical outlet 204. In one or more techniques, the detection may be performed with a device (not shown) attached to the plug 202 being powered and/or not being powered.

The example circuit diagram 200 illustrated in FIG. 2 can be extended to two or more, or multiple, electrical outlets 204. The illustrated PULSE signal 222, may be unique for one or more, or each, electrical outlet 204. In one or more techniques, the part of the example circuit diagram 200 inside of dashed line 210 may be repeated for one or more, or each, individual electrical outlet 204.

As illustrated in FIG. 2 a microcontroller 220 may drive the logic, perhaps for example based on firmware loaded in an internal flash memory (not shown). Resistors 230 and/or 231 may limit the current on the PULSE signal 222.

Capacitor 235 may isolate the circuitry from high voltage, have a low impedance to, for example, create an electrical path to ground (a short) for the PULSE signal 222 under some scenarios and have a (e.g., relatively very) high impedance for 50 Hz and/or 60 Hz power signals, for example, among other power signals.

Capacitor 236 may provide a short path to ground for PULSE signal 222, perhaps when a plug may be inserted. Capacitor 236 may act as a snubber circuit for relay 238 contacts, for example.

Relay contacts 238 may provide power for the device connected to the plug 202 that may be inserted into the electrical outlet 204 associated with the insertion detection circuit 200. A diode 240, for example a TVS diode, may protect at least some of the circuitry for high voltage bursts from the power line. The power line may include, as illustrated in FIG. 2, line 242 and neutral 243, for example.

A transistor 245 may be activated by a PULSE signal 222, perhaps for example when no plug 202 may be inserted into the electrical outlet 204 associated with the insertion detection circuit 200. A resistor 232 may serve as the collector load for transistor 245. A shunt resistor 233 may be used to measure the current consumption, perhaps for example when the relay 238 is on, among other scenarios.

In one or more techniques, the microcontroller 220 may be configured to generate a pulse signal, for example a ‘LOW-HIGH-LOW’ PULSE signal 222 out of port 221 with a (e.g., relatively very) short duration (e.g., for at least one circuit card assembly the duration may be 1 microsecond). The microcontroller 220 may be configured to check the value of an input DETECT signal 223, perhaps for example after the HIGH assertion of the ‘LOW-HIGH-LOW’ PULSE signal 222, among other scenarios. The microcontroller 220 may be configured to determine that a plug 202 is not inserted, perhaps for example if the value of the DETECT signal 223 is HIGH, among other scenarios. The microcontroller may be configured to determine that a plug 202 is inserted, perhaps for example if the value of the DETECT signal 223 is LOW, among other scenarios.

For example, if the plug is not inserted, there likely is no contact between a first pad/element/component 206 and a second pad/element/component 207. The PULSE signal 222 may be applied to transistor 245 through resistors 231 and 230 and/or may open the junction of transistor 245. In one or more techniques, if plug 202 is not inserted, the DETECT signal 223 may go and/or remain HIGH.

For example, if the plug 202 is inserted, there likely is contact between first pad/element/component 206 and second pad/element/component 207. The PULSE signal 222 may be shorted to ground 244 via resistor 230, capacitor 235, first pad/element/component 207, capacitor 236 and shunt resistor 233 (e.g., perhaps if relay 238 is open) and/or via resistor 230, capacitor 235, pad/element/component 207, relay 238, and shunt resistor 233 (e.g., perhaps if relay 238 is closed). The transistor 245 may stay closed and/or the DETECT signal 223 may go and/or stay LOW.

In one or more techniques, if the plug 202 is not inserted, the microcontroller 220 may drive relay 238 off via relay control lines 239, among other scenarios. This can be interpreted as there being no power on electrical outlet 204. In one or more techniques, if the plug 202 is inserted, the microcontroller 220 may drive relay 238 on via relay control lines 239, among other scenarios. This can be interpreted as there being power on electrical outlet 204 (e.g., whether the device connected to the plug is energized or not).

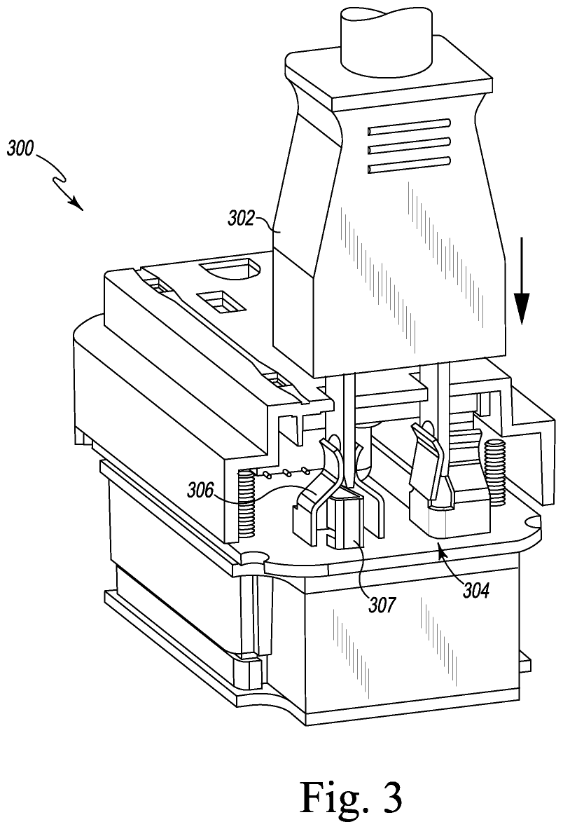

FIG. 3 illustrates an example electrical outlet insertion detection scenario 300. In scenario 300 a plug 302 is partially inserted into electrical outlet 304. In this position plug 302 may contact a first pad 306, but not contact a second pad 307. In this scenario one or more techniques may determine/detect a lack of insertion of plug 302 in electrical outlet 304.

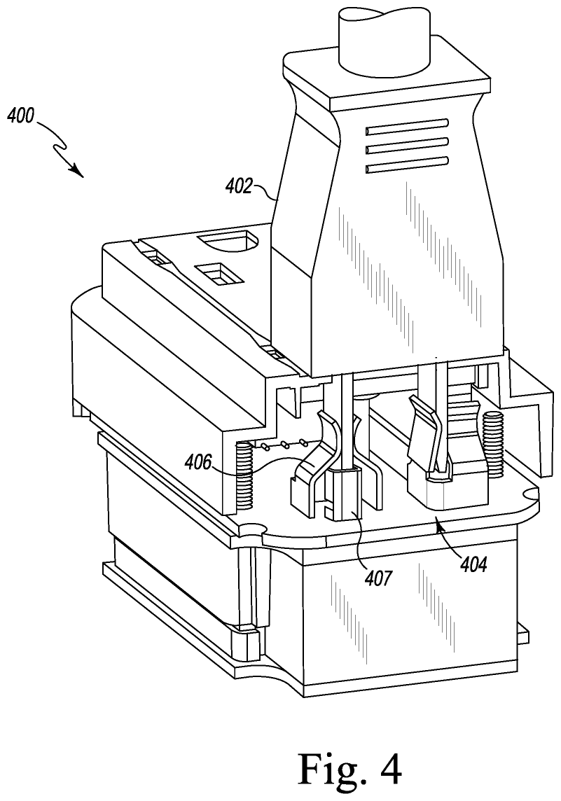

FIG. 4 illustrates an example electrical outlet insertion detection scenario 400. In scenario 400 a plug 402 is (e.g., substantially) fully inserted into electrical outlet 404. In this position plug 402 may contact a first pad 406 and contact a second pad 407. In this scenario one or more techniques may determine/detect an insertion of plug 402 in electrical outlet 404.

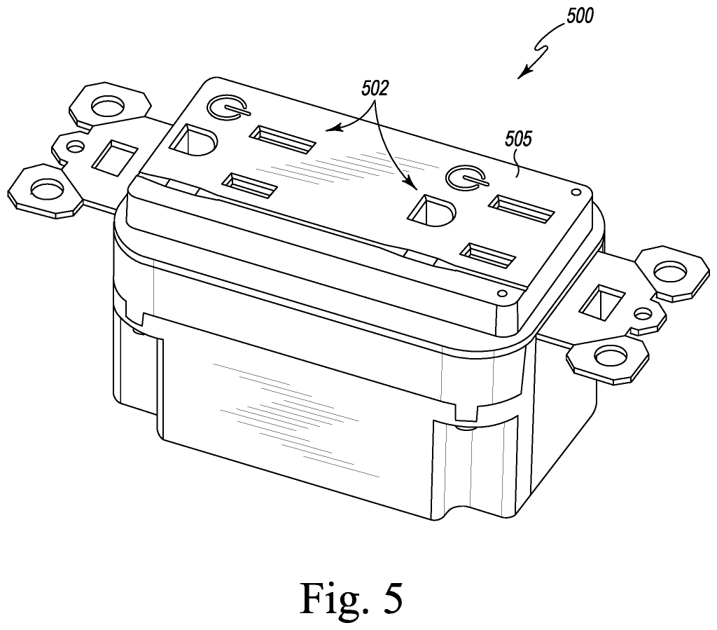

FIG. 5 is an example electrical outlet 500 that includes capacitive touch components (not shown) for an electrical outlet 500, either an in-wall electrical outlet and/or a power-cord-based electrical outlet. Electrical outlet 500 (e.g., an in-wall electrical outlet) with integral switches may provide the ability to turn on/off the power provided by the electrical outlet 500. Switching the power on/off can be done remotely (e.g., using wireless technology) and/or locally at the electrical outlet 500. Existing electrical outlets use a (e.g., relatively simple) mechanical button with access on the front plate of the electrical outlet for this control functionality.

In one or more techniques, a capacitive-touch-button array (not shown) may be used to locally control power for each of receptacles 502 of electrical outlet 500. The capacitive-touch-button array may be located on a circuit board (not shown) under the front plate 505 of the electrical outlet 500. Use of a capacitive-touch-button array may provide for a neater and/or cleaner look/appearance for the front plate 505 of electrical outlet 500. In the example illustration of FIG. 5, the front plate 505 may include (e.g., may only include) the regulatory markings for a controlled in-wall duplex electrical outlet and/or embedded LEDs for internal state representation, for example.

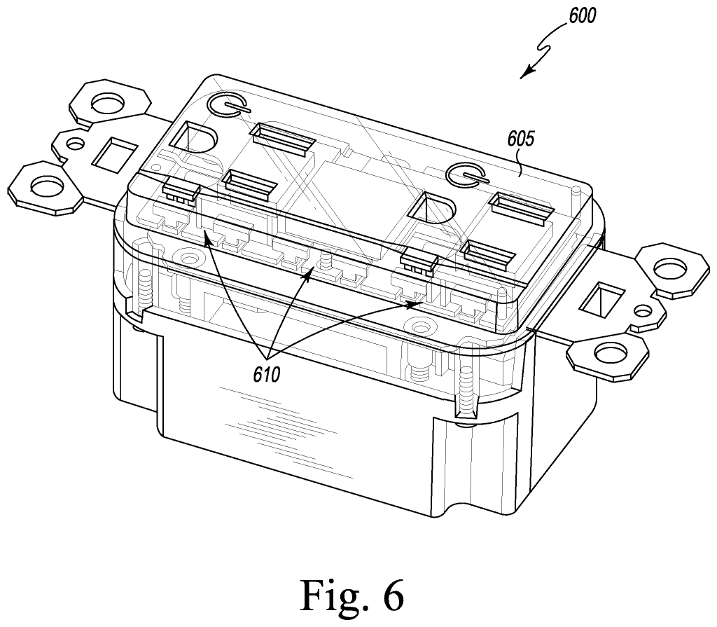

FIG. 6 is an example electrical outlet 600 that includes capacitive touch components. In FIG. 6, a capacitive-touch-button array 610 may be visible through a transparent front plate 605, for example. The capacitive-touch-button array 610 may provide for a (e.g., relatively) longer lifetime as compared to an existing regular push button(s), for example. A mechanical push button, perhaps depending on quality of the product, may practically guarantees a limited number of button actions, for example in the range of thousands to tens of thousands of actions. Perhaps because there is no mechanical action involved, among other reasons, the capacitive-touch-button array 610 may provide an (e.g., practically) unlimited lifetime.

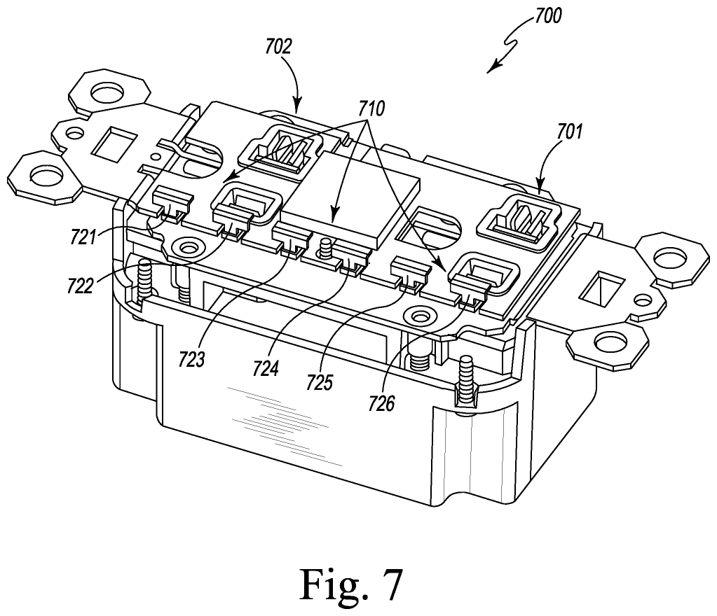

FIG. 7 is an example electrical outlet 700 that includes capacitive touch components, such as a capacitive-touch-button array (CTBA) 710. CTBA 710 may provide for a more diverse user interaction with electrical outlet 700. In one or more techniques, CTBA 710 may include one or more, or multiple, capacitive touch buttons (CTB). One or more, or each, of the capacitive touch buttons may be configured to perform individual functions and/or combined functions. An electrical outlet 700 may be configured with one or more different profiles for CTBA 710, including a factory-default functionality/profile for CTBA 710. A number of different profiles can be defined/configured and/or implemented for CTBA 710 in order to provide for the best-suited user experience.

In one or more techniques, the CTBA 710 may be configured with a factory default functionality/profile. Perhaps for example based on the user interaction capabilities, among other scenarios, CTBA 710 (e.g., CTBA 710 capabilities/functions) can be in at least one of the two states: IDLE or ACTIVE. For example, in an IDLE state, the CTBA 710 may have a limited functionality. In one or more techniques, the user can perform an (e.g., predetermined) action/gesture that may switch CTBA 710 into the ACTIVE state. For example, the (e.g., predetermined) action/gesture can be viewed as a protection (e.g., password) against changes made to electrical outlet 700 for status/function by an unauthorized user (e.g., a child) via CTBA 710.

One or more techniques may use one or more profiles. One or more CTBA 710 profiles may define if the CTBA 710 has an active mode (e.g., only), or idle/active modes, or not active at all (e.g., CTBA 710 disabled). One or more CTBA 710 profiles may define what user actions/gestures may switch the CTBA 710 from the IDLE state to the ACTIVE state. One or more CTBA 710 profiles may define what commands are available in the ACTIVE state (e.g., switch relays on/off, put the electrical outlet 700 into a provisioning mode and/or into the factory default mode, etc.). One or more CTBA 710 profiles may define how the CTBA 710 may switch back into the IDLE state (for example, after an inactive period of N seconds, and/or the like).

For example, referring to FIG. 7, in an IDLE state (e.g., only) CTB 723 and/or CTB 724 may be configured to read/detect user interaction. The rest of the CTBA 710 buttons may be inactive. Such a configuration may prevent accidental actions on the CTBA 710, for example. Perhaps in order to set the CTBA 710 in the ACTIVE state, among other reasons, a specific gesture may be performed on CTB 723 and/or CTB 724. For example, taping three times consecutively on CTB 723 and CTB 724 may place the CTBA 710 into the ACTIVE state.

In the ACTIVE state, one or more, or all the CTBA 710 buttons may be active and/or may be assigned one or more different and/or combined functions. For example, tapping for 3-5 seconds on CTB 723 and CTB 724 may set electrical outlet 700 into a provisioning mode. For example, tapping for more than 5 seconds on CTB 723 and CTB 724 may set the electrical outlet 700 into a factory default mode. For example, swiping from CTB 721, to CTB 722, to CTB 723 may toggle on/off outlet 701 (e.g., a first outlet of a duplex electrical outlet 700). For example, swiping from CTB 726, to CTB 725, to CTB 724 may toggle on/off outlet 702 (e.g., a second outlet of the duplex electrical outlet 700). For example, no action on the CTBA 710 for at least as long, or longer, than a pre-defined/predetermined time period/interval (e.g., twenty seconds) may set the CTBA 710 into/back into the IDLE state.

In one or more techniques, perhaps by way of a remote configuration and/or a local configuration, among other scenarios, the CTBA 710 capabilities can be disabled so that a user might not be able to interact locally with the CTBA 710 capabilities of the electrical outlet. For example, such a disabling feature may be useful to prevent a child's interaction (e.g., activate/deactivate) with the electrical outlet 700, or for certain security scenarios, among other scenarios.

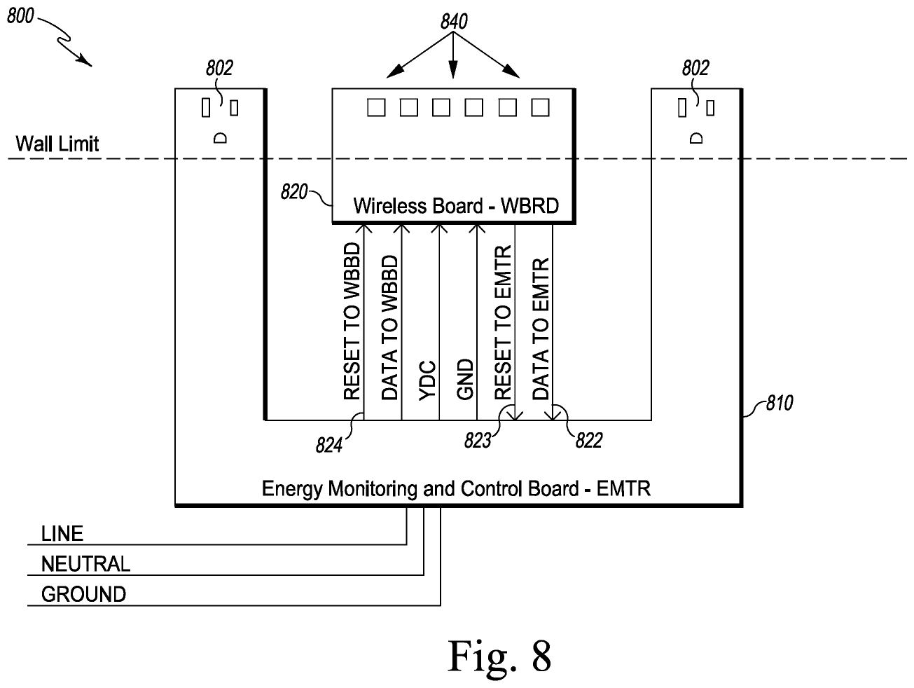

FIG. 8 illustrates an example of an electrical outlet modular architecture circuit diagram 800 for use as either an in-wall electrical outlet and/or a power-cord-based electrical outlet. In one or more techniques, the modular architecture may be “intelligent” and/or may include extended functional safety features.

In many instances, maybe except for (e.g., scheduled and/or unintentional) power outages and/or circuit breaker interruption, an electrical outlet may be powered continuously, perhaps with no (e.g., relatively easy) way to perform a power cycle on the electrical outlet. For various reasons, the firmware running on the internal microcontroller of the electrical outlet may find itself in an abnormal and/or nonfunctional state. A microcontroller in an abnormal and/or nonfunctional state may benefit from a hardware reset, for example, that may place the microcontroller into a more normal, regular and/or functional state. In many instances, a user may have limited interaction opportunities with the electrical outlet. As there may be limited opportunities for user interaction with the electrical outlet, there may be a corresponding lack of interaction opportunities with mechanical reset buttons, and/or similar reset devices, which may be mounted on or near the electrical outlet.

In one or more techniques, electrical outlets that include an intelligent architecture may take advantage of one or more existing features and/or may provide for (e.g., relatively) minimal chances for its microcontroller to enter into an abnormal and/or nonfunctional state. Referring to FIG. 8, an Emergency Monitoring and Control Board (EMTR) 810 may include an AC/DC converter (not shown) and one or more relays (not shown). For example, EMTR 810 may include at least one relay for one or more, or each, receptacle 802 of electrical outlet 800. The EMTR 810 may include a microcontroller (not shown). The EMTR 810 microcontroller may be configured to control one or more relays (e.g., on/off control, etc.). The EMTR 810 microcontroller may be configured to control/perform one or more of: voltage (V) and/or current (I) sampling, energy calculation(s), board temperature measurement(s), and/or plug insertion detection, and/or the like.

A Wireless Controller Board (WBRD) 820 may include a capacitive-touch-button array (CTBA) 840. The WBRD 820 may include one or more indicators (not shown), for example LED indicators, or the like. The WBRD 820 may include a microcontroller (not shown), the microcontroller may be configured to control/perform one or more of: CTBA 840 control, one or more LED indicator control, and/or wireless communication.

One or more components of the WBRD 820 and/or the EMTR 810 may be placed into an abnormal and/or nonfunctional state for various reasons, such as for example stack overflow and/or memory corruption, and/or the like. One or more techniques may provide for intrinsic functional safety of the WBRD 820 and/or the EMTR 810. One or more techniques may include a dual “watch dog.” For example, perhaps as part of the main execution flow control, among other scenarios, the WBRD 820 may send (e.g., periodically) commands (e.g., at least one command per second) to the EMTR 810 via a DATA-TO-EMTR signal 822. The EMTR 810 may reply back for one or more, or each, command, perhaps with a specific response per command, and/or a more general response per one or more commands.

Perhaps for example if the EMTR 810 may get into/be put into an abnormal and/or nonfunctional state and/or might not reply back to the WBRD 820 with a proper response, among other scenarios, the WBRD 820 may repeat the command for a (e.g., predetermined) number of times (e.g., three times). Perhaps for example after repeating the command, if a proper response is not detected from the EMTR 810, among other scenarios, the WBRD 820 may initiate a hardware reset to the EMTR 810 through a RESET-TO-EMTR signal 823.

In one or more techniques, the WBRD 820 may get into/be put into an abnormal and/or nonfunctional state and/or may stop sending (e.g., periodically) commands. The EMTR 810 may detect a lack of commands (e.g., too few commands over a period of time, or the like) from the WBRD 820 and/or may initiate a hardware reset to the WBRD 820 through a RESET-TO-WBRD signal 824, for example.

In one or more techniques, the EMTR 810 may have a (e.g., predetermined) timeout interval (e.g., four seconds). Perhaps for example if the EMTR 810 receives any command from the WBRD 820, the EMTR 810 may reset the timeout and/or start the timeout interval again. Perhaps for example if no command comes from the WBRD 820 by the expiration of the timeout interval, then the EMTR 810 may assume there is something wrong with the WBRD 820 and/or may initiate the reset signal to the WBRD 820. The duration of the timeout interval can be configured to one or more, or any, other value (for example two, five, or ten seconds, etc.). One or more techniques may provide for extrinsic functional safety of the WBRD 820 and/or the EMTR 810. One or more techniques may include some level of user interaction.

In one or more techniques, a user can trigger a hardware reset to the EMTR 810 by use of one or more capacitive-touch-button array (CTBA) 840 commands, and/or remotely via one or more wireless commands. Such user-interaction hardware resets may be useful, perhaps for example when a new (e.g., fresh and/or updated) firmware revision may have been loaded into the flash memory of EMTR 810 (e.g., which may require a hardware reset according to the configuration), among other scenarios.

There may be situations when the WBRD 820 may get into/be put into at least a partial abnormal and/or nonfunctional state. For example, the WBRD 820 may be sending (e.g., periodically) commands to the EMTR 810, while perhaps the wireless communication and/or one or more CTBA 840 control functions may be corrupted. One or more techniques may trigger a hardware reset to the WBRD 820. A plug may be inserted/extracted into/from at least one receptacle 802 of the electrical outlet 800 for a specific/predetermined number of times (e.g., five times), perhaps for example during a specific/predetermined time interval (e.g., fifteen seconds). Perhaps for example via plug insertion detection techniques, among other techniques, the EMTR 810 microcontroller may detect the succession of plug insertion/extraction cycles and/or may initiate a hardware reset to the WBRD 820 through the RESET-TO-WBRD signal 824.

One or more techniques may provide protection from current draw overload from the electrical outlet 800, either an in-wall electrical outlet and/or a power-cord-based electrical outlet. The overload protection may be provided on per-receptacle 802 basis of the electrical outlet 800, for example.

In many instances, electrical outlets are used in residential, commercial, and/or industrial environments for electrical circuits that may be rated at 15 Amps or 20 Amps, for example. According to one or more electrical construction standards, on a 15 Amp protected circuit, 15 Amp rated electric outlet(s) can be used (e.g., can only be used). On a 20 Amp protected circuit, 20 Amp rated electric outlet(s) and/or 15 Amp rated electrical outlets can be used (e.g., can only be used).

According to one or more electrical construction standards, each electrical circuit is to be protected from overload by a specialized device (e.g., an overload circuit breaker, fuse, and/or the like). In many instances, more than one electrical outlet may be served by the same electrical circuit. In such instances, the overload circuit breaker may (e.g., mostly) protect the circuit, and perhaps may protect the electrical outlets less so. For example, on a 20 Amp protected circuit, ten or more 20 Amp rated electrical outlets may be installed. One or more, or each, electrical outlet may support a 20 Amp load. In such scenarios, that can add up to 200 Amps of load on the 20 Amp protected circuit. The overload circuit breaker might not limit the current on the circuit to 20 Amps (e.g., only to 20 Amps). If the overload circuit breaker were rated on a value higher than 20 Amps, that may leave one or more of the electrical outlets unprotected if an electrical device (e.g., perhaps a defective electrical device) were plugged into one electrical outlet and the current draw/load on that electrical outlet may exceed 20 Amps (e.g., the rated current load for the electrical outlet).

In one or more techniques, an electrical outlet described herein may use at least two features to provide “intelligent” overload protection: the ability to control (e.g., on/off) one or more, or each, receptacle of an electrical outlet, and/or the ability to sample the current (load/draw) for one or more, or each, receptacle of an electrical outlet and/or compute instant, peak, and/or RMS (root mean square) values of the current load/draw(s).

One or more techniques may use at least two types of overload protection: overload protection based on instant/peak load value(s), and/or overload protection based on RMS load value(s). This may be useful because electrical consumers may have different load profiles, among other reasons. For example, for resistive-load-type consumers, where the load variation may be slow, the overload protection may be based on RMS value(s).

In one or more techniques, overload protection may be based on RMS current load/draw value(s). The microcontroller may compute RMS value(s) on successive short intervals (e.g., 1 second). The internal relay may be disconnected, perhaps for example if the RMS value(s) may be higher than a (e.g., specified/predetermined) value for a (e.g., specified/predetermined) number of consecutive intervals. For example, if the RMS value(s) are over 30 Amps for 15 consecutive seconds, the internal relay may be disconnected for the electrical outlet providing power to the connected electrical device. Several levels of RMS overload can be set to be active at the same time, for example: 30 Amps for 15 seconds, 40 Amps for 3 seconds, and/or 21 Amps for 60 seconds, etc. For example, if one or more of these RMS overload thresholds are exceeded, the internal relay may be disconnected for at least the electrical outlet providing power to the connected electrical device.

Different classes of consumers/devices (e.g., electric motors, tungsten, etc.) may have (e.g., may usually have) spikes in current consumption, such as inrush current, for example. Instant/peak load value(s) analysis may allow for differentiation between a “normal” inrush current and an abnormal current overload. For example, an electric motor may have a high inrush current at start, perhaps for example for one or two cycles at 60 Hz. The electric motor may then return to “normal” load current. The same electric motor, perhaps for example in the event the rotor stalls, among other scenarios, may draw a (e.g., relatively very) high current (e.g., six times the normal load current) continuously. The electric outlet may disconnect electrical service to the electric motor (e.g., via the internal relay), for example to prevent melting the contact(s).

In one or more techniques, overload protection may be based on instant/peak load value(s). The microcontroller may store the current load/draw peak value for the last N cycles. Perhaps for example if N is set to twenty cycles, the peak values for one third of a second (0.33 sec) of history may be stored (e.g., continuously). Perhaps for example if one or more, or all, the stored values are above a (e.g., predetermined) high limit (e.g., 60 Amps) then the internal relay may be disconnected for the electrical outlet providing power to the connected electrical device.

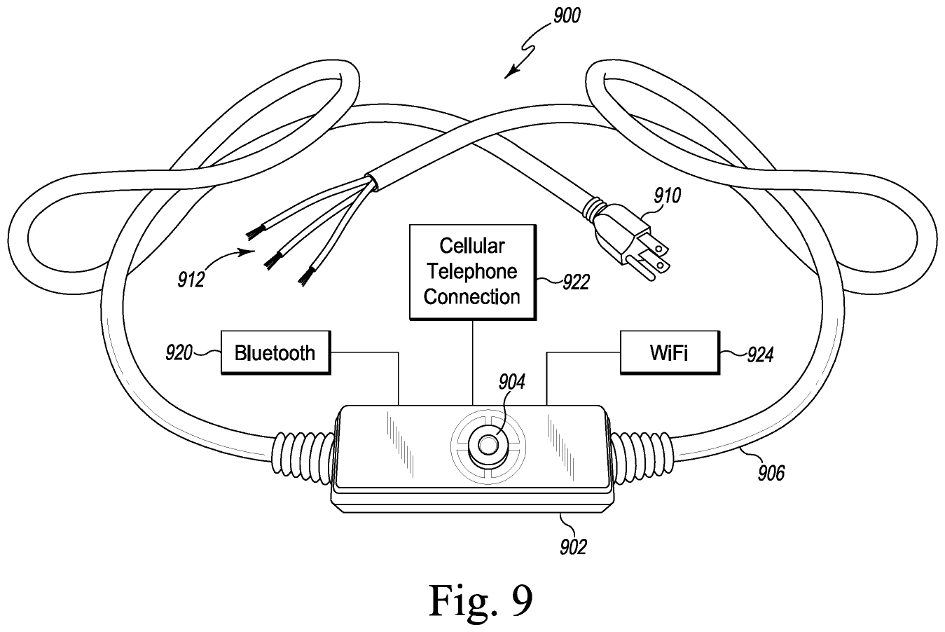

FIG. 9 is an example illustration of a power cord system 900, that may include the smart outlet circuitry 902 in line with a device (not shown) power cord 906 instead of inside the electrical outlet as previously disclosed. The power cord system 900 may also include: power switch 904, power cord first end 910, power cord second end 912. The circuitry 902 may include circuitry for wirelessly communicating with external devices, such as Bluetooth 920, cellular telephone connection 922, and WIFI 924, to name just a few nonlimiting examples.

The circuitry 902 may connect to, for example, external computing devices via, Bluetooth 920, cellular telephone connection 922, and WIFI 924. This may allow, for example, remote on/off control of the device coupled to the power cord system 900 (e.g. from a computer or smartphone). The power cord system 900 may include a display (not shown), to display some data collected and stored by the smart outlet system 900. That data may include: power on profile waveforms; voltage (high, low, average); current (high, low, average); power factor (high, low, average); cycle count, on and off duration time; total lifetime product on/run time; watts (high, low, average, total); email or text notifications to a user; data logging and ability to store the data in the cloud, to name just a few nonlimiting examples.

The circuitry 902 may be added to power cord 906 that is used to power, for example, an electrical device, so that the circuitry can monitor these and/or other electrical parameters, store these parameters, and communicate with an external computing device through at least the aforementioned wireless communication functions. The power cord system 900 may be electrically coupled to a device via the power cord second end 912, and electrically coupled to a power source, e.g, a wall outlet via the power cord first end 910.

While the present disclosure has been illustrated and described in detail in the drawings and foregoing description, the same is to be considered as illustrative and not restrictive in character, it being understood that only certain embodiments have been shown and described, and that all changes and modifications that come within the spirit of the present disclosure are desired to be protected.

What is claimed is:

1. A device for providing connection to electrical energy, the device comprising:
an electrical outlet, the electrical outlet comprises at least one electrical receptacle; and
a control circuit, the control circuit configured to at least:
generate one or more pluses;
determine at least one of:
an insertion into the at least one electrical receptacle, or a lack of an insertion into the at least one electrical receptacle, based on a measurement of the one or more generated pulses; and
indicate at least one of:
the insertion into the at least one electrical receptacle or the lack of an insertion into the at least one electrical receptacle.

2. The device of claim 1, wherein the device is an in-wall electrical outlet.

3. The device of claim 1, wherein the device is a power-cord-based electrical outlet.

4. The device of claim 1, wherein the control circuit includes a processor configured to control the electrical energy flow to the at least one electrical receptacle.

5. The device of claim 1, wherein the device is able to detect an insertion into the electrical receptacle whether an inserted device is powered or unpowered.

6. The device of claim 1, wherein the device comprises a capacitive touch array, the capacitive touch array configured to locally control power for the at least one electrical receptacle.

7. The device of claim 6, wherein the capacitive touch array is located on a circuit board under a front plate of the device.

8. The device of claim 6, wherein the capacitive touch array comprises a plurality of capacitive touch buttons, wherein the capacitive touch buttons control a plurality of functions of the at least one receptacle, based at least on a user interaction with the plurality of capacitive touch buttons.

9. The device of claim 1, wherein the device monitors a current load of the at least one receptacle by measuring at least one of: an instant current, one or more peak currents, and one or more root-mean-squared (RMS) currents, or a combination thereof.

10. The device of claim 1, wherein the one or more pulses are generated base on at least one of: a voltage measurement, a current measurement, an energy calculation, an insertion detection, and a board temperature measurement, or a combination thereof.

11. The device of claim 1, wherein the control circuit is configured to determine if a device is attached to the receptacle, when the device is powered and when the device is unpowered.

12. The device of claim 1, wherein the measurement comprises at least the electrical energy of the at least one receptacle, the electrical energy of the at least one receptacle is based on at least one of: an instant current measurement, a peak current measurement, a root-mean-squared (RMS) current measurement, or a combination thereof.

13. The device of claim 1, wherein the controller comprises a firmware, the firmware configured to reduce instances of a reset condition.

14. A system for providing connection to electrical energy, the system comprising:
an electrical outlet, the electrical outlet comprising at least one electrical receptacle; and
a control circuit, the control circuit configured to detect an insertion into the at least one electrical receptacle or a lack of an insertion into the at least one electrical receptacle.

15. The system of claim 14, wherein the system is structured to generate one or more pulses, wherein the one or more pulses being based on the insertion into the electrical receptacle or the lack of an insertion into the receptacle.

16. The system of claim 14, wherein the electrical outlet configuration is selected from at least: an in-wall electrical outlet and a power-cord-based electrical outlet.

17. The system of claim 14, wherein the system is able to detect the insertion into the at least one electrical receptacle whether an inserted device is powered or unpowered.

18. The system of claim 14, wherein the system comprises a capacitive touch array, the capacitive touch array is configured to locally control power for the at least one electrical receptacle.

19. The system of claim 18, wherein the capacitive touch array comprises a plurality of capacitive touch buttons, wherein the capacitive touch buttons are configured to control a plurality of function of the electrical receptacle, based at least on a user interaction with the plurality of capacitive touch buttons.

20. The device of claim 1, wherein the device monitors a current load of the at least one receptacle by measuring at least one of: an instant current, one or more peak currents, and one or more root-mean-squared (RMS) currents, or a combination thereof.
